(19) United States
(12) Patent Application Publication
(10) Pub. No.: US 2026/0051887 A1
(43) Pub. Date: Feb. 19, 2026

(54) INTEGRATED CIRCUIT WITH SLOW VOLTAGE INCREASE ACROSS FLOATING CAPACITOR

(71) Applicant: Chengdu Monolithic Power Systems Co., Ltd., Chengdu (CN)

(72) Inventor: Xiangyi Yang, Chengdu (CN)

(21) Appl. No.: 19/298,628

(22) Filed: Aug. 13, 2025

(30) Foreign Application Priority Data
Aug. 13, 2024 (CN) 202411110214.4

(51) Int. Cl. H03K 17/56

(52) U.S. Cl. CPC H03K 17/56; H03K 2217/0063; H03K 2217/0072

(57) ABSTRACT

An integrated circuit with slow voltage increase across the floating capacitor during the power on process of the integrated circuit is discussed. The integrated circuit has a charging path coupled between a power supply and a floating drive pin. The charging path has an ON resistance variable during a power on process of the integrated circuit.

### CROSS-REFERENCE TO RELATED APPLICATIONS

This application claims priority to and the benefit of Chinese Patent Application No. 202411110214.4, filed Aug. 13, 2024, which is incorporated herein by reference in its entirety.

### BACKGROUND OF THE INVENTION

A half bridge circuit typically includes a high side power switch HS and a low side power switch LS coupled in series between an input voltage VIN and a reference ground, as shown in FIG. 1. The common connection of the high side power switch HS and the low side power switch LS forms a switch node SW. When the high side power switch HS is turned on, the voltage at the switch node SW is pulled to the input voltage VIN; and when the low side power switch LS is turned on, the voltage at the switch node SW is pulled to the reference ground GND. Therefore, the voltage at the switch node SW is not fixed. When the high side power switch HS comprises an N-type switching device (such as N-type metal oxide semiconductor field-effect transistors), the turning-on condition is that the voltage difference between the control terminal G and the source terminal S is greater than the turning-ON threshold. However, due to the source terminal S is coupled to the switch node SW with an unstable voltage, a floating drive circuit is required to float drive the high side power switch HS. The so-called floating drive is to have a floating capacitor C_{BST} be coupled between the source terminal S of the high side power switch HS and the driving circuit. When the low side power switch LS is turned on, the floating capacitor C_{BST} is charged, so that the driving voltage provided by the driving circuit is always greater than or equal to the voltage at the source terminal S.

However, prior art typically adopts constant charging current to charge the floating capacitor C_{BST}. If the charging current is too small, the voltage across the floating capacitor C_{BST} would increase too slowly, causing the high side power switch HS to be not able to be turned on normally. If the charging current is too high, the voltage across the floating capacitor C_{BST} would increase too fast, which would probably prevent the voltage across the floating capacitor C_{BST} from being used for the initial state reset judgment, so that the system is unable to start normally, which may even result in damage of the floating capacitor.

Thus, an improvement is needed.

### SUMMARY OF THE INVENTION

In accordance with an embodiment of the present invention, an integrated circuit is discussed. The integrated circuit comprises: a first drive pin, a second drive pin, a switch pin, a floating drive pin, and a driving control circuit. The first drive pin is configured to provide a high side drive signal. The second drive pin is configured to provide a low side drive signal. The driving control circuit is configured to control a voltage difference between the floating drive pin and the switch pin by way of the floating drive pin, to have 1) the voltage difference between the floating drive pin and the switch pin increase slowly; and 2) an increase rate change from low to high during a power on process of the integrated circuit.

In addition, in accordance with an embodiment of the present invention, an integrated circuit is discussed. The integrated circuit comprises: a first drive pin, a second drive pin, a switch pin, a floating drive pin, and a charging path. The first drive pin is configured to provide a high side drive signal. The second drive pin is configured to provide a low side drive signal. The charging path is coupled between a power supply and the floating drive pin; wherein the charging path has an ON resistance variable during a power on process of the integrated circuit.

Furthermore, in accordance with an embodiment of the present invention, a half bridge circuit is discussed. The half bridge circuit comprises: a high side power switch, a low side power switch, a first drive terminal, a second drive terminal, a switch terminal, a floating drive terminal, and a charging path. The high side power switch and the low side power switch are coupled in series between an input voltage and a reference ground. The first drive terminal is configured to provide a high side drive signal, to control the high side power switch. The second drive terminal is configured to provide a low side drive signal, to control the low side power switch. The charging path is coupled between a power supply and the floating drive terminal and has an ON resistance variable during a power on process.

### BRIEF DESCRIPTION OF DRAWINGS

FIG. 1 schematically shows a typical circuit topology of a prior half bridge circuit.

FIG. 2 schematically shows an integrated circuit 200 in accordance with an embodiment of the present invention.

FIG. 3 schematically shows the timing waveform of the voltage V_{BST} across the floating capacitor C_{BST} in accordance with an embodiment of the present invention.

FIG. 4 schematically shows a circuit configuration of an integrated circuit 400 in accordance with an embodiment of the present invention.

FIG. 5 schematically shows a circuit configuration of an integrated circuit 500 in accordance with an embodiment of the present invention.

FIG. 6 schematically shows a circuit configuration of an integrated circuit 600 in accordance with an embodiment of the present invention.

FIG. 7 schematically shows a circuit configuration of the charging path 21 in accordance with an embodiment of the present invention.

FIG. 8 schematically shows a circuit configuration of the charging path 21 in accordance with another embodiment of the present invention.

FIG. 9 schematically shows a circuit configuration of the charging path 21 in transistor array level in accordance with an embodiment of the present invention.

FIG. 10 schematically shows a circuit configuration of an integrated circuit 1000 in accordance with an embodiment of the present invention.

### DETAILED DESCRIPTION OF THE INVENTION

Embodiments of circuits for integrated circuit are described in detail herein. In the following description, some specific details, such as example circuits for these circuit components, are included to provide a thorough understanding of embodiments of the invention. One skilled in relevant art will recognize, however, that the invention can be practiced without one or more specific details, or with other methods, components, materials, etc.

The following embodiments and aspects are illustrated in conjunction with circuits and methods that are meant to be exemplary and illustrative. In various embodiments, the above problem has been reduced or eliminated, while other embodiments are directed to other improvements.

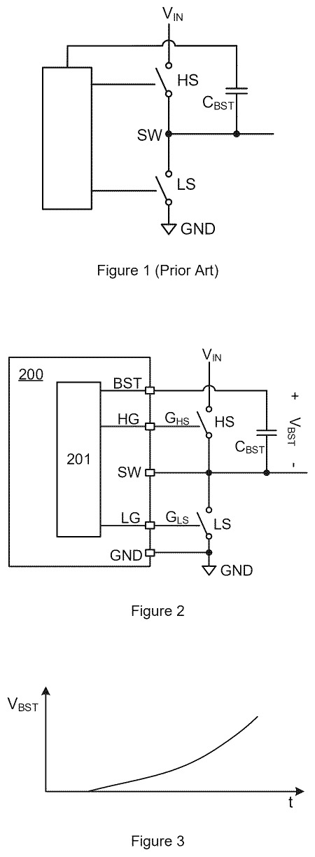

FIG. 2 schematically shows an integrated circuit 200 in accordance with an embodiment of the present invention. In the example of FIG. 2, the integrated circuit 200 is used to drive a half bridge circuit. The half bridge circuit comprises: a high side power switch HS and a low side power switch LS coupled in series between the input voltage VIN and a reference ground GND. The integrated circuit 200 comprises: a first drive pin HG, a second drive pin LG, a switch pin SW, a floating drive pin BST, and a ground pin GND. The first drive pin HG is externally coupled to a control terminal of the high side power switch HS, to provide a high side drive signal GHs, to control the high side power switch HS to be turned on and off. The second drive pin LG is externally coupled to a control terminal of the low side power switch LS, to provide a low side drive signal Gus, to control the low side power switch LS to be turned on and off. The switch pin SW is externally coupled to a common connection node (i.e. a switch node) of the high side power switch HS and the low side power switch LS. The floating drive pin BST is externally coupled to the switch pin SW via a floating capacitor C_{BST}. That is, the floating capacitor C_{BST} is coupled between the floating drive pin BST and the switch pin SW. The ground pin GND is externally coupled to the reference ground.

In one embodiment of the present invention, the high side power switch HS and the low side power switch LS both include controllable switch devices such as gallium nitride field-effect transistors (GaN FETs), metal oxide semiconductor field-effect transistors (MOSFETs), bipolar transistors (BJTs), and etc.

In one embodiment of the present invention, when the low side power switch LS is turned on, the floating capacitor C_{BST} is charged, and a voltage difference V_{BST} between the floating drive pin BST and the switch pin SW (i.e., the voltage across the floating capacitor C_{BST}) starts to increase. When the low side power switch LS is turned off, the floating capacitor C_{BST} is temporarily suspended from being charged, and the voltage difference V_{BST} between the floating drive pin BST and the switch pin SW maintains or slightly decreases.

During the power on process of the integrated circuit 200, the voltage difference V_{BST} between the floating drive pin BST and the switch pin SW increases slowly, and the increase rate of the voltage V_{BST} changes from low to high. That is, at the beginning, when the voltage difference V_{BST} between the floating drive pin BST and the switch pin SW is relatively small, the charging amplitude of the floating capacitor C_{BST} is relatively small, and the voltage growth is relatively slow. When the voltage difference V_{BST} increases to a certain voltage value, the increase rate increases. FIG. 3 schematically shows the timing waveform of the voltage V_{BST} across the floating capacitor C_{BST} in accordance with an embodiment of the present invention.

In one embodiment of the present invention, the integrated circuit 200 further comprises: a driving control circuit 201, configured to control the voltage difference V_{BST} between the floating drive pin BST and the switch pin SW by way of the floating drive pin BST, to have 1) the voltage difference V_{BST} between the floating drive pin BST and the switch pin SW increase slowly; and 2) an increase rate change from low to high during the power on process of the integrated circuit 200. In one embodiment of the present invention, the driving control circuit 201 is configured to provide the charging current to the floating capacitor CBT via the floating drive pin BST. When the integrated circuit 200 is initially powered on, the charging current is relatively small. When the voltage difference Vest between the floating drive pin BST and the switch pin SW increases to a certain voltage value, the charging current increases.

In one embodiment of the present invention, the high side drive signal GHs and the low side drive signal Gus are provided by the driving control circuit 201.

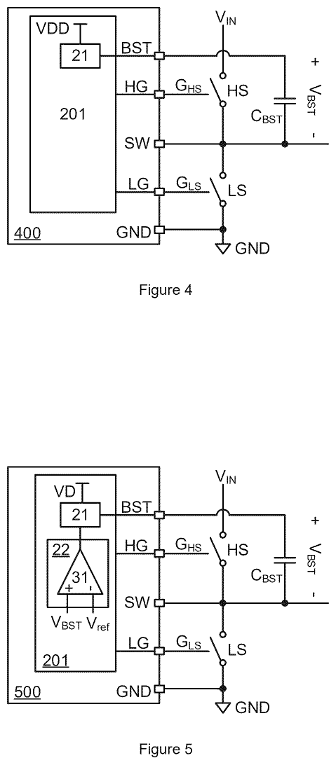

In one embodiment of the present invention, the driving control circuit 201 is configured to charge the floating capacitor CBsr by way of a charging path with variable resistance. As shown in FIG. 4, a circuit configuration of an integrated circuit 400 is schematically shown in accordance with an embodiment of the present invention. In the example of FIG. 4, the driving control circuit 201 comprises: a charging path 21, coupled between a power supply VDD and the floating drive pin BST. When the integrated circuit 400 is initially powered on, the charging path 21 has a relatively high ON resistance, e.g., a first ON resistance; and when the voltage difference V_{BST} between the floating drive pin BST and the switch pin SW increases to a certain voltage value, the on resistance of the charging path 21 decreases, e.g., the charging path 21 has a second ON resistance lower than the first ON resistance.

In one embodiment of the present invention, when the integrated circuit 400 is initially powered on, the charging path 21 has a relatively high ON resistance, e.g., a first ON resistance; when the voltage difference V_{BST} between the floating drive pin BST and the switch pin SW increases to a first voltage value, the ON resistance of the charging path 21 decreases, e.g., the charging path 21 has a second ON resistance lower than the first ON resistance; and when the voltage difference V_{BST} between the floating drive pin BST and the switch pin SW continues to increase to a second voltage value, the ON resistance of the charging path 21 further decreases, e.g., the charging path 21 has a third ON resistance lower than the second ON resistance.

That is, the charging path 21 has at least two different ON resistances during the power on process of the integrated circuit 400, to have the voltage difference V_{BST} between the floating drive pin BST and the switch pin SW increase slowly, and the increase rate changes from low to high.

In one embodiment of the present invention, the power supply VDD is configured to power various functional blocks in the integrated circuit.

FIG. 5 schematically shows a circuit configuration of an integrated circuit 500 in accordance with an embodiment of the present invention. In the example of FIG. 5, the driving control circuit 201 further comprises: a comparison circuit 22, configured to compare the voltage difference V_{BST} between the floating drive pin BST and the switch pin SW with a reference voltage V_{ref}. When the voltage difference V_{BST} between the floating drive pin BST and the switch pin SW is lower than the reference voltage V_{ref}, the charging path 21 is controlled to have the first ON resistance; and when the voltage difference V_{BST} between the floating drive pin BST and the switch pin SW is higher than the reference voltage V_{ref}, the charging path 21 is controlled to have a second ON resistance. The first ON resistance is higher than the second ON resistance.

In the example of FIG. 5, the comparison circuit 22 comprises a comparator 31, configured to compare the voltage difference V_{BST} between the floating drive pin BST and the switch pin SW with the reference voltage V_{ref}.

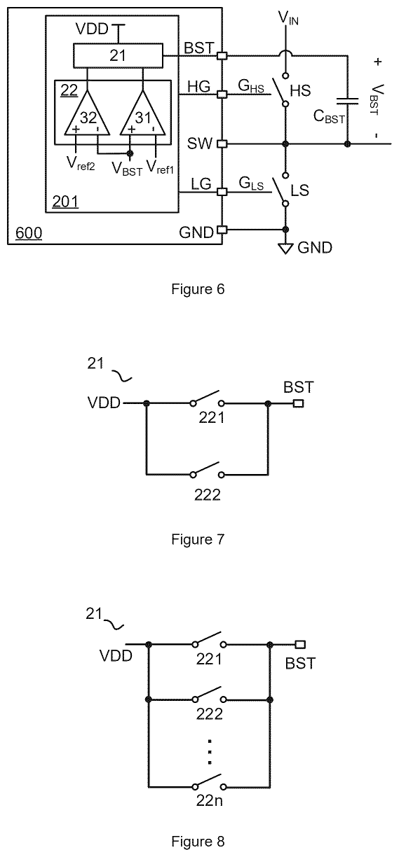

FIG. 6 schematically shows a circuit configuration of an integrated circuit 600 in accordance with an embodiment of the present invention. In the example of FIG. 6, the driving control circuit 201 further comprises: a comparison circuit 22, configured to compare the voltage difference V_{BST} between the floating drive pin BST and the switch pin SW with a first reference voltage V_{ref1} and a second reference voltage V_{ref2}. When the voltage difference V_{BST} between the floating drive pin BST and the switch pin SW is lower than the first reference voltage V_{ref1}, the charging path 21 is controlled to have the first ON resistance; when the voltage difference V_{BST} between the floating drive pin BST and the switch pin SW is higher than the first reference voltage V_{ref1} and lower than the second reference voltage V_{ref2}, the charging path 21 is controlled to have a second ON resistance; and when the voltage difference V_{BST} between the floating drive pin BST and the switch pin SW is higher than the second reference voltage V_{ref2}, the charging path 21 is controlled to have a third ON resistance. The first ON resistance is higher than the second ON resistance, and the second ON resistance is higher than the third ON resistance.

In the example of FIG. 6, the comparison circuit 22 comprises: a first comparator 31, configured to compare the voltage difference V_{BST} between the floating drive pin BST and the switch pin SW with the first reference voltage V_{ref1}; and a second comparator 32, configured to compare the voltage difference V_{BST} between the floating drive pin BST and the switch pin SW with the second reference voltage V_{ref2}.

FIG. 7 schematically shows a circuit configuration of the charging path 21 in accordance with an embodiment of the present invention. In the example of FIG. 7, the charging path 21 comprises: a first sub path 221 and a second sub path 222, coupled in parallel between the power supply VDD and the floating drive pin BST. When the voltage difference V_{BST} between the floating drive pin BST and the switch pin SW is lower than the reference voltage V_{ref}, the first sub path 221 is turned on (i.e., the floating drive pin BST is charged by the voltage supply VDD through this first sub path 221), causing the charging path 21 to have a first ON resistance. When the voltage difference V_{BST} between the floating drive pin BST and the switch pin SW is higher than the reference voltage V_{ref}, the second sub path 222 is turned on (i.e., the floating drive pin BST is charged by the voltage supply VDD through this second sub path 222), causing the charging path 21 to have a second ON resistance. In one embodiment of the present invention, when the voltage difference V_{BST} between the floating drive pin BST and the switch pin SW is higher than the reference voltage V_{ref}, the first sub path 221 is disabled (i.e. disconnected), and only the second sub path 222 is turned on. Accordingly, the floating drive pin BST is charged by the power supply VDD only through the second sub path 222. In other embodiments of the present invention, when the voltage difference V_{BST} between the floating drive pin BST and the switch pin SW is higher than the reference voltage V_{ref}, both the first sub path 221 and the second sub path 222 are turned on, allowing the floating drive pin BST to be charged by the supply voltage VDD through both the first sub path 221 and the second sub path 222, so that the ON resistance of the charging path 21 is reduced.

The example shown in FIG. 7 includes the first sub path 221 and the second sub path 222. However, one skilled in the art should realize that the charging path 21 may comprise any desired number of sub paths. As shown in FIG. 8, a circuit configuration of the charging path 21 is schematically shown in accordance with an embodiment of the present invention. In the example of FIG. 8, the charging path 21 comprises: a first sub path 221, a second sub path, . . . , and an n^{th} sub path 22n, coupled between the power supply VDD and the floating drive pin BST in parallel. N is an integer larger than 1. That is, the charging path 21 comprises at least two sub paths, coupled in parallel between the power supply VDD and the floating drive pin BST. When the voltage difference V_{BST} between the floating drive pin BST and the switch pin SW is within a first voltage window (e.g., lower than the first reference voltage V_{ref1}), part of the sub paths (e.g., the first sub path 221) is turned on, so that the charging path has a first ON resistance; when the voltage difference V_{BST} between the floating drive pin BST and the switch pin SW is within a second voltage window (e.g., higher than the first reference voltage V_{ref1} and lower than the second reference voltage V_{ref2}), more sub paths (e.g., both the first sub path 221 and the second sub path 222) are turned on, so that the charging path has a second ON resistance lower than the first ON resistance; and when the voltage difference V_{BST} between the floating drive pin BST and the switch pin SW is within a third voltage window (e.g., higher than the second reference voltage V_{ref2}), even more sub paths (e.g., the first sub path 221, the second sub path 222, . . . , and the n^{th} sub path 22n) are turned on, so that the charging path has a third ON resistance lower than the second ON resistance.

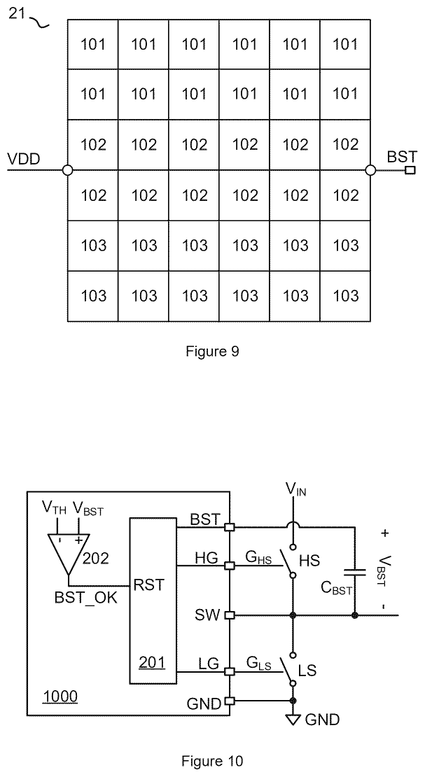

FIG. 9 schematically shows a circuit configuration of the charging path 21 in transistor array level in accordance with an embodiment of the present invention. As shown in FIG. 9, the charging path 21 comprises a plurality of switching elements (e.g., 101, 102, and 103). In one embodiment of the present invention, the switching element may comprise a wafer package. The driving control circuit 201 is configured to turn on different quantity of switching elements when the voltage difference V_{BST} between the floating drive pin BST and the switching pin SW is within different voltage windows. For example, when the voltage difference V_{BST} between the floating drive pin BST and the switch pin SW is within the first voltage window (e.g., lower than the first reference voltage V_{ref1}), a first part of the switching elements (e.g., 101) are turned on, causing the charging path 21 to have a first ON resistance. When the voltage difference V_{BST} between the floating drive pin BST and the switch pin SW is within the second voltage window (e.g., higher than the first reference voltage V_{ref} and lower than the second reference voltage V_{ref2}), a second part of the switching elements (e.g., 102) are also turned on (i.e., both the switching elements 101 and the switching elements 102 are turned on), causing the ON resistance of the charging path 21 to be reduced. When the voltage difference V_{BST} between the floating drive pin BST and the switch pin SW is within the third voltage window (e.g., higher than the second reference voltage V_{ref2}), a third part of the switching elements (e.g. 103) are also turned on (i.e., the switching elements 101, the switching elements 102, and the switching elements 103 are all turned on), causing the ON resistance of the charging path 21 to be further reduced.

In one embodiment of the present invention, the ON resistance of the charging path 21 no longer changes and maintains at a small value when the integrated circuit finishes the power on process, so that the voltage across the floating capacitor C_{BST} is quickly charged up when the low side power switch LS is ON during the normal operation of the half bridge circuit.

FIG. 10 schematically shows a circuit configuration of an integrated circuit 1000 in accordance with an embodiment of the present invention. In the example of FIG. 10, the integrated circuit 1000 further comprises: a startup comparator 202, configured to compare the voltage difference V_{BST} between the floating drive pin BST and the switch pin SW with a threshold voltage VTH. When the voltage difference V_{BST} between the floating drive pin BST and the switch pin SW is higher than the threshold voltage VTH, the startup comparator 202 is configured to provide a bootstrap normal signal BST_OK, which is used to reset various latches. For example, the bootstrap normal signal BST_OK may be used to reset the drive control circuit 201 (e.g., a reset terminal RST), to have the drive control circuit 201 start up normally; or the bootstrap normal signal BST_OK may be used to reset other functional blocks (e.g., a miller clamp block used for avoiding shot through between the high side power switch and low side power switch) of the integrated circuit 1000.

Several embodiments of the forgoing integrated circuit and the half bridge circuit set the charging path with different ON resistances, so as to have the voltage at the floating drive pin increase slowly, to protect the floating capacitor during the power on progress. In addition, such solution also allows the voltage comparator to have enough time to detect whether the voltage across the floating capacitor reaches the threshold voltage, so that various functional blocks could be initialized normally, ensuring a normal start up. The charging path maintains a relatively low resistance after the power on process, ensuring the voltage across the floating capacitor to be charged up fast.

It is to be understood in these letters patent that the meaning of “A” is coupled to “B” is that either A and B are coupled to each other as described below, or that, although A and B may not be coupled to each other as described above, there is nevertheless a device or circuit that is coupled to both A and B. This device or circuit may include active or passive circuit elements, where the passive circuit elements may be distributed or lumped-parameter in nature. For example, A may be coupled to a circuit element that in turn is coupled to B.

This written description uses examples to disclose the invention, including the best mode, and also to enable a person skilled in the art to make and use the invention. The patentable scope of the invention may include other examples that occur to those skilled in the art.

1. An integrated circuit, comprising:
a first drive pin, configured to provide a high side drive signal;
a second drive pin, configured to provide a low side drive signal;
a switch pin;
a floating drive pin; and
a driving control circuit, configured to control a voltage difference between the floating drive pin and the switch pin by way of the floating drive pin, to have 1) the voltage difference between the floating drive pin and the switch pin increase slowly; and 2) an increase rate change from low to high during a power on process of the integrated circuit.

2. The integrated circuit of claim 1, wherein the driving control circuit comprises:
a charging path, coupled between a power supply and the floating drive pin; wherein the charging path has an ON resistance variable during the power on process of the integrated circuit.

3. The integrated circuit of claim 2, wherein:
the charging path has a relatively high ON resistance when the integrated circuit is initially powered on; and
the ON resistance of the charging path is reduced when the voltage difference between the floating drive pin and the switch pin increases to a certain voltage value.

4. The integrated circuit of claim 2, wherein the driving control circuit further comprises:
a comparison circuit, configured to compare the voltage difference between the floating drive pin and the switch pin with a reference voltage; and wherein when the voltage difference between the floating drive pin and the switch pin is lower than the reference voltage, the charging path is controlled to have a first ON resistance; and
when the voltage difference between the floating drive pin and the switch pin is higher than the reference voltage, the charging path is controlled to have a second ON resistance.

5. The integrated circuit of claim 2, wherein the driving control circuit further comprises:
a comparison circuit, configured to compare the voltage difference between the floating drive pin and the switch pin with a first reference voltage and a second reference voltage; wherein
when the voltage difference between the floating drive pin and the switch pin is lower than the first reference voltage, the charging path is controlled to have a first ON resistance;
when the voltage difference between the floating drive pin and the switch pin is higher than the first reference voltage and lower than the second reference voltage, the charging path is controlled to have a second ON resistance; and
when the voltage difference between the floating drive pin and the switch pin is higher than the second reference voltage, the charging path is controlled to have a third ON resistance.

6. The integrated circuit of claim 2, wherein the charging path comprises a plurality of switching elements, and wherein:
the driving control circuit is configured to turn on different quantity of switching elements when the voltage difference between the floating drive pin and the switching pin is within different voltage windows.

7. The integrated circuit of claim 1, further comprising:
a startup comparator, configured to compare the voltage difference between the floating drive pin and the switch pin with a threshold voltage; when the voltage difference between the floating drive pin and the switch pin is higher than the threshold voltage, the startup comparator is configured to provide a bootstrap normal signal.

8. An integrated circuit, comprising:
a first drive pin, configured to provide a high side drive signal;
a second drive pin, configured to provide a low side drive signal;
a switch pin;
a floating drive pin; and
a charging path, coupled between a power supply and the floating drive pin; wherein the charging path has an ON resistance variable during a power on process of the integrated circuit.

9. The integrated circuit of claim 8, wherein:
the charging path has a relatively high ON resistance when the integrated circuit is initially powered on; and
the ON resistance of the charging path is reduced when a voltage difference between the floating drive pin and the switch pin increases to a certain voltage value.

10. The integrated circuit of claim 8, wherein:
when a voltage difference between the floating drive pin and the switch pin is lower than a reference voltage, the charging path is controlled to have a first ON resistance; and
when the voltage difference between the floating drive pin and the switch pin is higher than the reference voltage, the charging path is controlled to have a second ON resistance.

11. The integrated circuit of claim 8, wherein:
when a voltage difference between the floating drive pin and the switch pin is lower than a first reference voltage, the charging path is controlled to have a first ON resistance;
when the voltage difference between the floating drive pin and the switch pin is higher than the first reference voltage and lower than a second reference voltage, the charging path is controlled to have a second ON resistance; and
when the voltage difference between the floating drive pin and the switch pin is higher than the second reference voltage, the charging path is controlled to have a third ON resistance.

12. The integrated circuit of claim 8, wherein the charging path comprises a plurality of switching elements, and wherein:
different quantity of switching elements are turned on when a voltage difference between the floating drive pin and the switching pin is within different voltage windows.

13. The integrated circuit of claim 8, further comprising:
a startup comparator, configured to compare a voltage difference between the floating drive pin and the switch pin with a threshold voltage; when the voltage difference between the floating drive pin and the switch pin is higher than the threshold voltage, the startup comparator is configured to provide a bootstrap normal signal.

14. The integrated circuit of claim 8, wherein the charging path comprises:
a first sub path and a second sub path, coupled in parallel between a power supply and the floating drive pin; and wherein:
when a voltage difference between the floating drive pin and the switch pin is lower than a reference voltage, the first sub path is turned on; and
when the voltage difference between the floating drive pin and the switch pin is higher than the reference voltage, both the first sub path and the second sub path are turned on.

15. A half bridge circuit, comprising:
a high side power switch and a low side power switch, coupled in series between an input voltage and a reference ground;
a first drive terminal, configured to provide a high side drive signal, to control the high side power switch;
a second drive terminal, configured to provide a low side drive signal, to control the low side power switch;
a switch terminal;
a floating drive terminal; and
a charging path, coupled between a power supply and the floating drive terminal;
wherein the charging path has an ON resistance variable during a power on process.

16. The half bridge circuit of claim 15, wherein:
the charging path has a relatively high ON resistance at an initial stage of the power on process; and
the ON resistance of the charging path is reduced when a voltage difference between the floating drive terminal and the switch terminal increases to a certain voltage value.

17. The half bridge circuit of claim 15, wherein:
when a voltage difference between the floating drive terminal and the switch terminal is lower than a reference voltage, the charging path is controlled to have a first ON resistance; and
when the voltage difference between the floating drive terminal and the switch terminal is higher than the reference voltage, the charging path is controlled to have a second ON resistance.

18. The half bridge circuit of claim 15, wherein:
when a voltage difference between the floating drive terminal and the switch terminal is lower than a first reference voltage, the charging path is controlled to have a first ON resistance;
when the voltage difference between the floating drive terminal and the switch terminal is higher than the first reference voltage and lower than a second reference voltage, the charging path is controlled to have a second ON resistance; and
when the voltage difference between the floating drive terminal and the switch terminal is higher than the second reference voltage, the charging path is controlled to have a third ON resistance.

19. The half bridge circuit of claim 15, wherein the charging path comprises a plurality of switching elements, and wherein:
different quantity of switching elements are turned on when a voltage difference between the floating drive terminal and the switching terminal is within different voltage windows.

20. The half bridge circuit of claim 14, further comprising:
a startup comparator, configured to compare a voltage difference between the floating drive terminal and the switch terminal with a threshold voltage; when the voltage difference between the floating drive terminal and the switch terminal is higher than the threshold voltage, the startup comparator is configured to provide a bootstrap normal signal.
